(19) United States
(12) Patent Application Publication
(10) Pub. No.: US 2006/0037639 A1
(43) Pub. Date: Feb. 23, 2006

(54) Method of increasing the output power from photovoltaic cells

(76) Inventor: Bachir Hihi, Algiers (DZ)

Correspondence Address: Abellman, Frayne & Schwab, 666 Third Avenue, 10th Floor, New York, NY, 10017-5621, US

(21) Appl. No.: 10/528,646

(22) PCT Filed: Nov. 18, 2002
(86) PCT No.: PCT/DZ02/00002

§ 371 Date: Sep. 21, 2005

(30) Foreign Application Priority Data
Sep. 21, 2002 (DZ) 020232

(51) Int. Cl. H01L 25/00

(52) U.S. Cl. 136/246

(57) ABSTRACT

The invention relates to a method of increasing the output power from photovoltaic cells with different known systems and of reducing to a minimum the temperature of photovoltaic cells, which negatively affects the voltage. The system used to perform the invention method comprises prisms which are disposed on several adjacent surfaces, forming angles therebetween, and calculated such that all of the refracted light rays converge fully on the surface of the solar module. The material used for said prisms absorbs most of the ultraviolet rays.

The present invention relates to a method of increasing the output power from photovoltaic cells with different known systems and of reducing to a minimum the temperature of photovoltaic cells, which negatively affects the voltage.

### STATUS OF THE PREVIOUS ART

Throughout the world, the production of energy has three main origins: nuclear, fossil and hydraulic. Energy consumption in USA, for example, is 1200 TWh. In France, nuclear power represents 70% of the French energy consumption. The cost of production in USA is as follows: 3.88 cents/KWh for nuclear, 1.87 cents/KWh for fossil and 0.36 cents/KWh for hydraulic.

The disadvantages of the nuclear and fossil power are:

Pollution, the wastes of nuclear and coal (fossil); and their energy is non renewable and can be exhausted in future. Solar energy doesn't present any of these disadvantages and it is inexhaustible.

The industries, which are developing photovoltaic units, use one or two of the following systems:

The mono-crystalline silicone by which the cells attain a yield of 23% and the units which produce from 10% to 14%. The commercialization price of these units is in the range of US$ 5 to 6 perwaft.

The units of the semi-crystalline silicone formed a quarter of the international photovoltaic sales in 1988 and their production is between 12% and 13%. The amorphous silicone has a weak production, which is about 7%, and because of that its production becomes expensive.

“The Electric Power Research Institute” (USA), government agency, has concluded that the photovoltaic systems should reach to a production of 15% and at the cost of US$ 2.00 per watt, established to being in a position to enter in competition with the other conventional sources.

The conclusion relates to a production of 2,700 KWh/year/W (Sunshine 300 day/year/9h/day, amortization over 20 years) and therefore at a price of solar KWh equal to (US$ 2.20): 2.7=3.70 cents.

The Influence of temperature on the photovoltaic cells:

The output power of a photovoltaic cell falls down when temperature increases. FIG. 4 illustrates that such loss is essentially due to a reduction of the voltage of short circuit.

It is known that for the solar cell, that its current is very little affected by the temperature. In other terms, when the radiation intensity increases, the voltage in the opened circuit varies a little then the current of the short circuit takes a large variation, and when the temperature increases, the voltage in the opened circuit underlines a large variation, and the current of the short circuit a small variation.

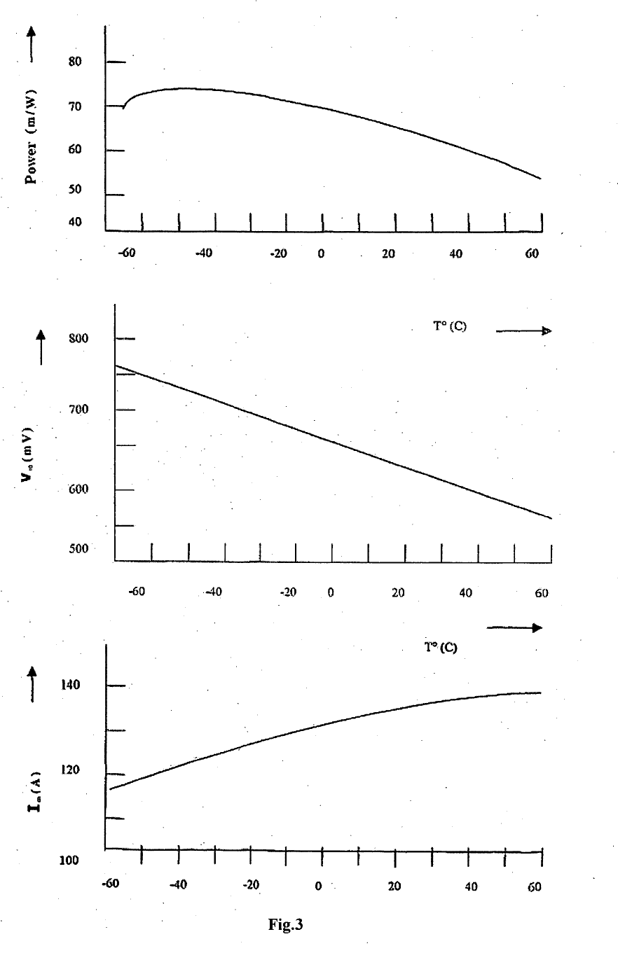

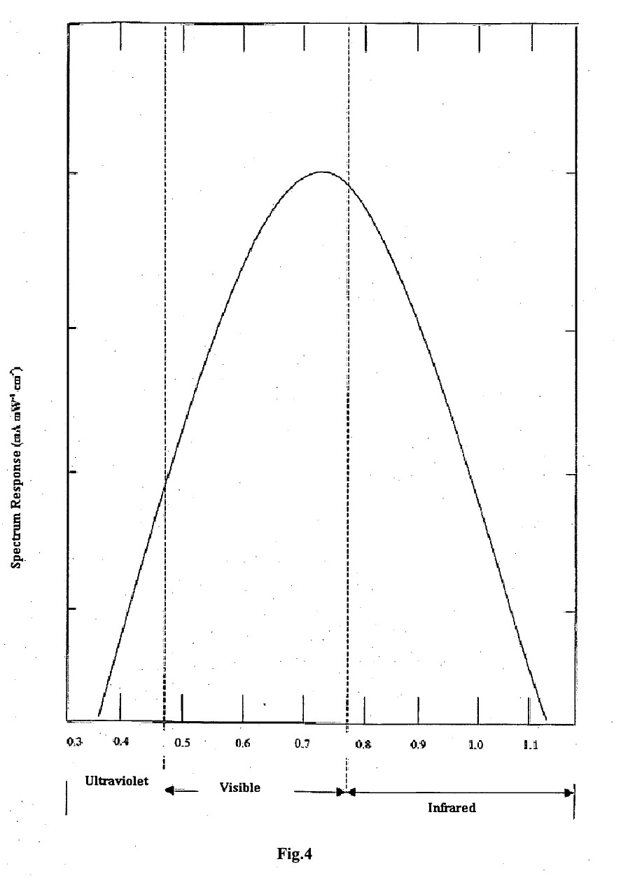

The spectrum of the solar rays spreads into the ultraviolet passing through the visible and the infrared at distance. The photovoltaic cells, in general, are insensible to light outside the visible and the very near infrared. This characteristic is reflected in the FIG. 3 which mentions the response curve of a conventional photovoltaic cell.

The solar light emits energy in the bands of ultra violets and infrareds, and the band of the visible one as well.

The quantity of the emitted energy varies according to the following formula:
E=h.c/λ

Where: h=the constant of PLANK, c=velocity of the light, λ=length of the wave.

When the length of the wave decreases, the energy quantity increases. With this increase in the intensity in a logarithmic manner, while the length of wave decreases, the electromagnetic energy becomes the most important in the band of the ultra violets.

All system increased light intensity increases the current and also the output power of the solar cell. But, at the same time, all the energy that has not been transformed into electricity increases the temperature of the solar cell and as enunciated, the voltage diminishes.

### PRESENTATION OF THE INVENTION ESSENCE

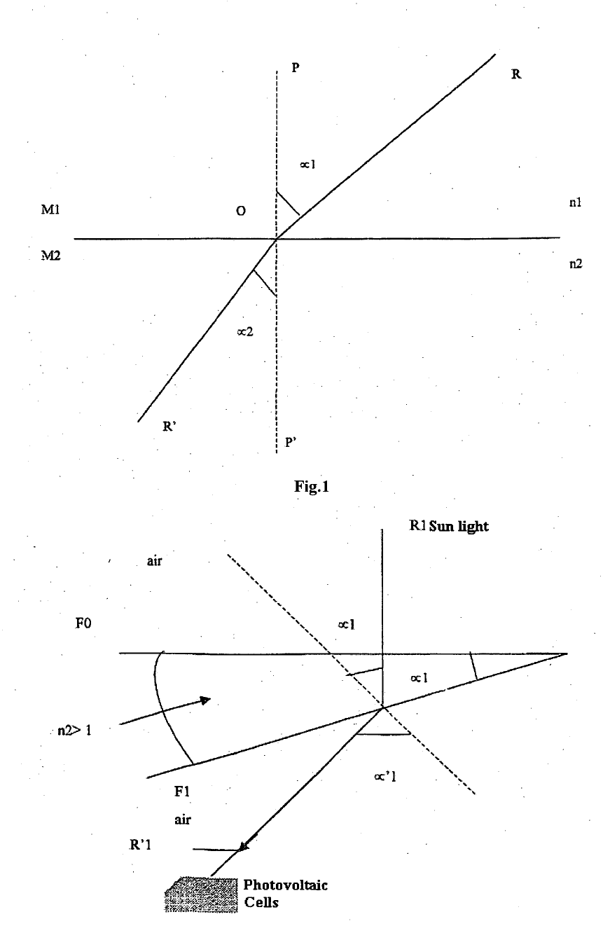

Mode of concentration with multi prisms: recalling physical data: consider 2 transparent mediums, M1 and M2, having respectively as an index of refraction: n1 and n2 (FIG. 1).

All light rays “R” will be refracted in 0 following R′. If α1 is the angle between R and the perpendicular pp′, then R′ is an angle α2 with pp′, that will be connected with α1 by this relation:
nl.sin α1=n2.sin α2

We consider a multi prisms with 2 faces F0 and F1 (FIG. 2) which makes a α1 angle between them and has an index of refraction n2>1 (index of the air).

The perpendicular solar ray R1 with F0 will continue its way without deviation, until meeting face F1 where it will be reflected in R′1 to make an angle α′1>α1.

R′1 is directed to the photovoltaic cell. The surface of the face F1 will be calculated in a manner so that all the rays falling on the surface will be refracted to cover all the surface of the photovoltaic cell.

Other adjacent faces F2 . . . Fn with different angles will deviate and juxtapose all the light rays received on the entire surface of the photovoltaic cell.

So, the photovoltaic cell will receive much of the sunshine which falls at the faces, certainly with consideration to absorption of some luminosity at a level of multi prisms as well as the cosines of the solar rays with the photovoltaic cell.

When the clarity of the light is considerably increased, the intensity of the short circuit current automatically increases, without affecting the inertia of the open circuit, which means we increase the output power.

This system of concentration supposes that the entire installation (multi prisms and units) must follow the sun (tracking system).

Theoretically, for a factor of concentration comprising between 2 and 10, it isn't necessary to cool the photovoltaic cell, in a measure that the electric proprieties of these cells have been determined as of the departure of the internal resistance which is relatively weak.

In the case of partial or total elimination of ultraviolet rays, the elevation of due temperature to the concentration has no much influence on the tension, and we obtain with the multi prisms an increase in the output power of the units in the order of 4 to 5 times'the nominal power.

### MODE OF REALIZING THE INVENTION

The system used to realize the procedure of the invention comprises prisms which are located on several adjacent surfaces forming angles there between, calculated in a manner that all the refracted light rays converge fully on the surface of the solar module.

Each face is consisted of a number of similar multi prisms. The method of the invention allows to considerably increasing the power of the nominal output of the existent solar units.

This is translated by a substantial decrease of the cost of the solar KWh that becomes, thus, very competitive to the cost of nuclear power and can be also very competitive to the fossil power. Therefore, the large scale application throughout the world becomes realizable due to the economic feasibility.

Among these realizations, the list of which is not at all exhaustive, we indicate for example: pumping water into arid areas, lighting isolated localities, desalination of saline water, production and transportation of direct current under high tension to long distances, and telecommunications and the cathode protection.

1-6. (canceled)

7. A method for the deviation of the sun's rays in a determined direction with the aid of a prism that has an index of super refraction to 1, the surface of the deviated luminous rays being determined by a number of prisms, the adjacent faces of which are directed to reflect the received light rays on the sole surface of the photovoltaic cells, the faces of which are made of a transparent material which absorbs the sun's ultraviolet rays, the solar panel being equipped with a fluid or electric system which ensures that it is always directed toward the sun.

8. A method according to claim 7, wherein the surface of the deviated luminous rays is determined by a number of identical prisms which cover the surface of the face.

9. A method according to claim 1, wherein all of the adjacent faces at different angles are directed so that they reflect the received light on the sole surface of the photovoltaic cells.
